(19) United States
(12) Patent Application Publication
(10) Pub. No.: US 2014/0206982 A1
(43) Pub. Date: Jul. 24, 2014

(54) METHOD AND APPARATUS FOR IMPLEMENTING A POSITRON EMISSION TOMOGRAPHY

(71) Applicant: SIEMENS AKTIENGESELLSCHAFT, Munich, DE (US)

(72) Inventor: Sebastian SCHMIDT, Weisendorf (DE)

(73) Assignee: Siemens Aktiengesellschaft, Munich (DE)

(21) Appl. No.: 14/156,890

(22) Filed: Jan. 16, 2014

(30) Foreign Application Priority Data
Jan. 23, 2013 (DE) 102013201009.5

(51) Int. Cl. G01R 33/48

(52) U.S. Cl. CPC G01R 33/481
USPC 600/411

(57) ABSTRACT

A method is disclosed for implementing a positron emission tomography of an examination object. In an embodiment of the method, after introducing a PET tracer into the examination object, the method includes implementing at least one functional magnetic resonance tomography for determining at least one respective measure of the activation of at least one respective brain area; implementing positron emission tomography; and adjusting a result of the positron emission tomography as a function of the at least one respective measure of the activation of at least one respective brain area. An embodiment of the present invention further describes an apparatus for implementing a positron emission tomography of an examination object.

### PRIORITY STATEMENT

The present application hereby claims priority under 35 U.S.C. §119 to German patent application number DE 102013201009.5 filed Jan. 23, 2013, the entire contents of which are hereby incorporated herein by reference.

### FIELD

At least one embodiment of the present invention generally relates to a method for implementing a positron emission tomography. Additionally, at least one embodiment of the present invention generally relates to a corresponding apparatus for implementing a positron emission tomography.

### BACKGROUND

In the examination and diagnostics of neurological and psychiatric diseases, the two imaging methods magnetic resonance tomography, MRT, and positron emission tomography, PET, complement one another in an ideal manner. In positron emission tomography, a large number of tracers or PET tracers, in other words in most instances radioactively marked substances produced naturally in the body or foreign to the body, which can be introduced into the metabolism of a living organism, are available, which bind very specifically to receptors, for instance for neurotransmitters, and can be verified with high sensitivity. Magnetic resonance tomography offers high temporal and spatial resolution and the possibility of displaying the anatomy of a living organism. Receptor binding studies using PET are known for instance.

To this end a PET tracer, which has similar binding behavior to a neurotransmitter, is administered to the patient. This binds to a receptor if the natural ligand is not already bound. Such tracers thus allow statements to be made about the receptor density and occupation. One disadvantage is however the slow kinetics. The PET signal effectively represents the integral of the accumulation over time or the “incubation duration”, generally 20-30 minutes. A tracer or radiotracer is therefore usually injected into a patient and there is then a wait for this time span before a first image is produced.

However, with many PET tracers the accumulation is dependent on the state of the patient during the accumulation phase. Different distributions thus already result for the standard glucose (FOG) PET as a function of whether the patient has his eyes open or closed, once the tracer has been injected. The same applies to physical activity. An increased accumulation occurs on account of the increased metabolism in the active brain areas, such as visual center or motor center. This becomes problematic in the examination and diagnostics of psychiatric and some neurological diseases.

With depression for instance, a change is indicated in the activation of neuronal networks, which are associated with introspection, i.e. preoccupation with oneself, e.g. in the rostrolateral prefrontal cortex. If during the accumulation of the tracer the patient is in a specific state, e.g. in a state of deep relaxation, asleep or solving arithmetic problems, a falsified result is produced. The state of a patient can conversely only be influenced with difficulty, since even the patient himself can only have a deliberate influence to a certain extent.

By contrast functional magnetic resonance tomography fMRT has better temporal resolution and is capable of representing the change in activation with a resolution in the range of a few, for instance ten, seconds. Nevertheless, with functional magnetic resonance tomography, only the change in oxygen usage in the blood, the so-called BOLD effect or BOLD contrast, (Blood Oxygen Level Dependent), is measured, which is very non-specific.

### SUMMARY

At least one embodiment of the present invention is directed to specifying a method, which allows for an improved implementation of a positron emission tomography. Furthermore, at least one embodiment of the invention describes a corresponding apparatus with which at least one embodiment of such a method can be implemented.

A method is disclosed for implementing a positron emission tomography and an apparatus is disclosed for implementing a positron emission tomography.

The basic idea behind at least one embodiment of the invention is a method for implementing a positron emission tomography of an examination object, wherein after PET tracer is introduced into the examination object, the method including:

S1) Implementing at least one functional magnetic resonance tomography for determining at least one measure of the activation of at least one predeterminable brain area in each instance;
S2) Implementing a positron emission tomography; and
S3) Adjusting the result of the positron emission tomography as a function of the at least one measure of the activation of at least one predeterminable brain area.

A further basic idea behind an embodiment of the invention is an apparatus for implementing a positron emission tomography of an examination object. The apparatus includes a positron emission tomography device, an MRT device and a computing and control unit, wherein the MRT device is embodied to this end, after inserting a PET tracer into the examination object, to implement at least one functional magnetic resonance tomography in order to determine at least one measure of the activation of at least one predeterminable brain area respectively and to make the at least one measure available to the computing and control unit. The positron emission tomography device is embodied so as to implement a positron emission tomography of the examination object and to make the result available to the computing and control unit. The computing and control unit is configured to this end so as to adjust the result of the positron emission tomography of the examination object as a function of the at least one measure of the activation of the at least one predeterminable brain area.

The computing and control unit can be embodied for instance as a computer, or the functions can be integrated in the positron emission tomography device or in the MRT device. The computing and control unit can be equipped with data interfaces with the positron emission tomography and MRT devices, so that data, in particular image data, can be routed from these devices to the computing and control unit. The computing and control unit is furthermore configured to this end so as to adjust the result of the positron emission tomography of the examination object as a function of the at least one measure of the activation of the at least one predeterminable brain area, by it having a corresponding computer program for instance, which executes these functions. The computing and control unit preferably has an input device, e.g. a computer keyboard, for entering threshold values for instance or controlling the method. The computing and control unit further advantageously has an output device, e.g. a computer monitor, for outputting a result of an adjusted positron emission tomography.

In an advantageous development, the apparatus is configured to execute one of the previously described methods.

The computing and control unit in particular can also be configured here by a computer program, which is stored in the memory of the computing and control unit, and is processed so as to execute one of the previously described methods. The apparatus preferably has further devices, which are configured to execute one of the previously described methods. For instance, the apparatus may have a lamp, in order to wake a patient if an unwanted sleeping state is detected.

The positron emission tomography device and the MRT device are particularly advantageously combined in a PET-MRT device and the PET-MRT device and the computing and control unit is configured so as to execute a previously described, embodiment of the inventive method.

### BRIEF DESCRIPTION OF THE DRAWINGS

Further advantageous developments result from the figures and the description which follow, in which;

FIG. 1 shows by way of example a flow chart of an embodiment of an inventive method for implementing a positron emission tomography of an examination object;

FIG. 2 shows by way of example activity curves of the Default Mode Network and the Task Positive Network;

FIG. 3 shows by way of example a PET tracer accumulation curve;

FIG. 4 shows a symbolic representation of an apparatus for implementing a positron emission tomography of an examination object.

### DETAILED DESCRIPTION OF THE EXAMPLE EMBODIMENTS

The present invention will be further described in detail in conjunction with the accompanying drawings and embodiments. It should be understood that the particular embodiments described herein are only used to illustrate the present invention but not to limit the present invention.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

The basic idea behind at least one embodiment of the invention is a method for implementing a positron emission tomography of an examination object, wherein after PET tracer is introduced into the examination object, the method including:
S1) Implementing at least one functional magnetic resonance tomography for determining at least one measure of the activation of at least one predeterminable brain area in each instance;
S2) Implementing a positron emission tomography; and
S3) Adjusting the result of the positron emission tomography as a function of the at least one measure of the activation of at least one predeterminable brain area.

This basic idea of at least one embodiment of the inventive method for implementing a positron emission tomography of an examination object is thus based on a PET tracer being introduced into the examination object, for instance a human or animal patient, e.g. by way of injection or inhalation. A PET tracer or a radiopharmaceutical is generally understood to mean a radioactively marked substance in a small quantity, which is introduced into a living organism and takes part in the metabolism of the living body, since it cannot be distinguished by the organism from its non-radioactive pendant. Over time the PET tracer accumulates in characteristic regions as a function of the carrier substance and the organism and can be detected by the radioactive decay with the aid of a positron emission tomography device. PET tracers in various embodiments for various fields of application are well known in clinical and scientific practice.

In an embodiment, in the first method step, at least one functional magnetic resonance tomography is implemented, in order to determine at least one measure of the activation of at least one predeterminable brain area in each instance. It is thus possible to determine the state of the examination object after administering the tracer and in particular to distinguish between various neuronal networks, which function with different neurotransmitters.

In an embodiment, in the second method step, a positron emission tomography is implemented. Here the properties of the positron emission tomography can be used advantageously, in particular the high detection sensitivity of the tracers bound specifically to receptors. The results of a positron emission tomography are reconstructed sectional images, which visualize the distribution of the radiopharmaceutical in the organism, i.e. render visible biochemical and physiological functions.

Inan embodiment, in the third and last method step of this basic idea of an embodiment of the inventive method, the result of the positron emission tomography is adjusted as a function of the at least one measure of the activation of the at least one predeterminable brain area. The adjustment of the result can take place for instance by reducing the result values, if, in the first method step, a measure of the activation of the predetermined brain area exceeds a predeterminable threshold value. The type and measure of the adjustment, the selection of a brain area and the threshold value can be determined in advance for instance by series of measurements or preliminary studies.

Advantageously the determination of the at least one measure of the activation of brain areas is implemented repeatedly by functional magnetic resonance tomography, wherein the repetition rate can be predetermined. Or the method steps S2 to S3 are executed repeatedly, wherein the repetition rate can be predetermined.

When repeating the determination of the at least one measure of the activation of at least one brain area respectively, a sequence of activation values is obtained over time. I.e. possible changes in state of the patient during the accumulation of the tracer are identified and can be advantageously taken into account when adjusting the result of the positron emission tomography as a function of the at least one measure of the activation of the at least one predeterminable brain area. It is also conceivable to execute the first method step repeatedly until a determined measure of the activation has achieved a predeterminable threshold value and only then branch to the second method step.

In an example embodiment of the invention, the repeated determination of the at least one measure of the activation of brain areas by functional magnetic resonance tomography takes place at least during the period of time of accumulation of the PET tracer.

In this embodiment, the measurement thus extends from brain area activations and if necessary the repeated implementation of positron emission tomographies and the adjustment of the results, at least beyond the accumulation phase of the PET tracer.

In an advantageous development, the predeterminable brain areas are determined by brain areas of the Default Mode Network and/or brain areas of the Task Positive Network.

The Default Mode Network, DMN, Task Negative Network, TNN, “awareness network” or “resting state network”, is understood in neuroscience generally to mean a group of brain areas which are active when “doing nothing” and are deactivated in the event of a concentrated mental task. The rest activity of these brain areas can be proven for instance with functional magnetic resonance tomography, electroencephalography and magnetoencephalography. By correlating the activity of these brain areas, this group of synchronously active brain areas can be summarized as a network. Medial prefrontal cortex, praecuneus, parts of the gyrus cinguli, and also the lobulus parietalis superior of the parietal lobe and the hippocamus belong to the participating brain areas. It is assumed that the Default Mode Network is also active if a person is daydreaming for instance. With various neurological and psychiatric diseases, for instance Alzheimers, the Default Mode Network can change. While the Task Negative Network is deactivated for instance when resolving tasks, the Task Positive Network, TPN, is activated. There is also the view that TNN and TPP are components of a network which operate in a negatively correlated fashion. Brain areas of the Default Mode Network and/or brain areas of the Task Positive Network are thus preferred brain areas for monitoring the state of the examination object.

In a further advantageous embodiment of the invention, the predeterminable brain areas are determined by brain areas of the Default Mode Network and by brain areas of the Task Positive Network and the adjustment of the result of the positron emission tomography is determined as a function of the relationship from the measures of the activity distribution of the Default Mode Network and of the Task Positive Network.

In this embodiment, the times with a vast Default Mode Network activity and Task Positive Network activity are thus determined in each instance and related to one another. The results of the positron emission tomography are then adjusted as a function of the relationship. If the Task Positive Network Activity takes precedence for instance, the results of the positron emission tomography are rejected, i.e. for instance multiplied by zero.

In an alternative embodiment of the invention, a warning is output if a measure of the at least one measure of the activation of at least one predeterminable brain area respectively lies outside of a predeterminable tolerance range.

In this embodiment, a tolerance range can be predetermined by a user for instance, e.g. a tolerance range for Task Positive Network Activity. After at least one measure of the activation of a predeterminable brain area, e.g. a brain area which describes the Task Positive Network Activity has been determined, a check is carried out to determine whether the measure lies outside of the predetermined tolerance range. If this is the case, a warning is output, e.g. in the form of a text on a computer monitor, in order to indicate to a user that the examination object is not in a state which is required for a correct result of a positron emission tomography.

A further advantageous embodiment provides that the time during which the at least one measure of the activation of the respective at least one predeterminable brain area is above a determinable threshold value is included in the adjustment of the result of the positron emission tomography.

Just brief activation of an unwanted brain area can if necessary be ignored, a state of the examination object which is not wanted for determining a positron emission tomography over a longer period of time can by contrast render the result unuseable.

It has proven advantageous for the at least one measure to be compared with an activation threshold value after the at least one measure of the activation of brain areas has been determined and if the at least one measure of the activation of brain areas is greater than the activation threshold value, a predeterminable action is executed, in particular the outputting of an acoustic and/or optical and/or tactile signal.

If by monitoring the activation of a brain area, which describes the Default Mode Network, it is determined that a patient has fallen asleep, a signal from the group of acoustic, optical or tactile signals can restore the patient into an awake state. An acoustic signal may be the sounding of an alarm sound, an optical signal may be the illumination of a lamp, a tactile signal may be for instance the impact of a patient's leg against a foam hammer.

An accumulation of the PET tracer in the examination object over time is usefully included in the adjustment of the result of the positron emission tomography.

Since the accumulation does not take place evenly over time, the contribution can be weighted accordingly during the individual phases. To this end, a kinetics can be assumed for instance, e.g. across a calibration curve, which was determined in advance by test measurements.

It is conceivable for the accumulation of the PET tracer in the examination object to be approximated over time by way of a predeterminable saturation function or to be determined by a measurement with a PET MRT device.

The accumulation of the PET tracer in the examination object can follow a saturation kinetics, which can be described for instance by a mathematical model, e.g. by a logarithmic function. Alternatively, it is possible to measure the accumulation with the aid of a combined MR-PET device, by the accumulation being determined over time in the PET.

A segmentation of the brain is preferably included in the determination of the at least one measure of the activation of at least one predeterminable brain area in each instance, said segmentation being determined by way of a measurement of the accumulation of the PET tracer with the PET part of a PET-MRT device and transmitted to an MRT image, which was obtained with the MRT part of the PET-MRT device.

In order to monitor the networks, in particular automatically, a segmentation of the corresponding brain areas is required. With the advantageous use of a combined MR-PET device, the segmentation can take place with the aid of PET accumulation and can be transmitted to the MR images. This is advantageous since these brain areas in the PET indicate a very specific accumulation, depending on the tracer, and can be easily segmented by way of predeterminable threshold values.

A brain atlas is particularly advantageously included in the determination of the at least one measure of the activation of at least one predeterminable brain area in each instance.

Alternatively, the brain areas can be determined by registration with an atlas. Segmentation algorithms are methods of medical image processing which are known per se, for which there are various realization proposals in scientific literature.

A further basic idea behind an embodiment of the invention is an apparatus for implementing a positron emission tomography of an examination object. The apparatus includes a positron emission tomography device, an MRT device and a computing and control unit, wherein the MRT device is embodied to this end, after inserting a PET tracer into the examination object, to implement at least one functional magnetic resonance tomography in order to determine at least one measure of the activation of at least one predeterminable brain area respectively and to make the at least one measure available to the computing and control unit. The positron emission tomography device is embodied so as to implement a positron emission tomography of the examination object and to make the result available to the computing and control unit. The computing and control unit is configured to this end so as to adjust the result of the positron emission tomography of the examination object as a function of the at least one measure of the activation of the at least one predeterminable brain area.

The computing and control unit can be embodied for instance as a computer, or the functions can be integrated in the positron emission tomography device or in the MRT device. The computing and control unit can be equipped with data interfaces with the positron emission tomography and MRT devices, so that data, in particular image data, can be routed from these devices to the computing and control unit. The computing and control unit is furthermore configured to this end so as to adjust the result of the positron emission tomography of the examination object as a function of the at least one measure of the activation of the at least one predeterminable brain area, by it having a corresponding computer program for instance, which executes these functions. The computing and control unit preferably has an input device, e.g. a computer keyboard, for entering threshold values for instance or controlling the method. The computing and control unit further advantageously has an output device, e.g. a computer monitor, for outputting a result of an adjusted positron emission tomography.

In an advantageous development, the apparatus is configured to execute one of the previously described methods.

The computing and control unit in particular can also be configured here by a computer program, which is stored in the memory of the computing and control unit, and is processed so as to execute one of the previously described methods. The apparatus preferably has further devices, which are configured to execute one of the previously described methods. For instance, the apparatus may have a lamp, in order to wake a patient if an unwanted sleeping state is detected.

The positron emission tomography device and the MRT device are particularly advantageously combined in a PET-MRT device and the PET-MRT device and the computing and control unit is configured so as to execute a previously described, embodiment of the inventive method.

By combining the positron emission tomography device and MRT device in one device, the advantages result such as for instance a defined position of the examination object in both images, so that if necessary, no registration of MRT images and positron emission tomography images is needed.

The example embodiments described in more detail below represent preferred embodiment variants of the present invention.

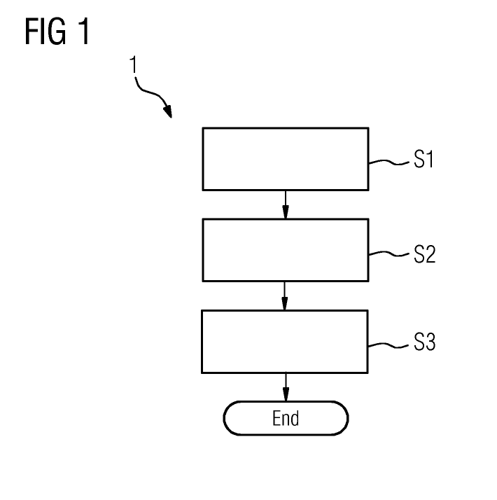

FIG. 1 shows by way of example a flow chart of an embodiment of an inventive method 1 for implementing a positron emission tomography of an examination object. The method 1 includes the method steps S1 to S3. It begins with method step S1 and ends “End” after method step S3. The individual method steps are as follows:

S1) Implementing at least one functional magnetic resonance tomography for determining at least one measure of the activation of at least one predeterminable brain area in each instance;
S2) Implementing positron emission tomography; and
S3) Adjusting the result of the positron emission tomography as a function of the at least one measure of the activation of at least one predeterminable brain area.

The determination of the at least one measure of the activation of brain areas is preferably repeatedly executed by functional magnetic resonance tomography, in other words method step S1, with a repetition rate which is predetermined by a user for instance. Or the method steps S1 to S3 are repeatedly executed with a predetermined repetition rate. If an abort criterion to be tested, e.g. the actuation of a button, is fulfilled, the repetition can be interrupted.

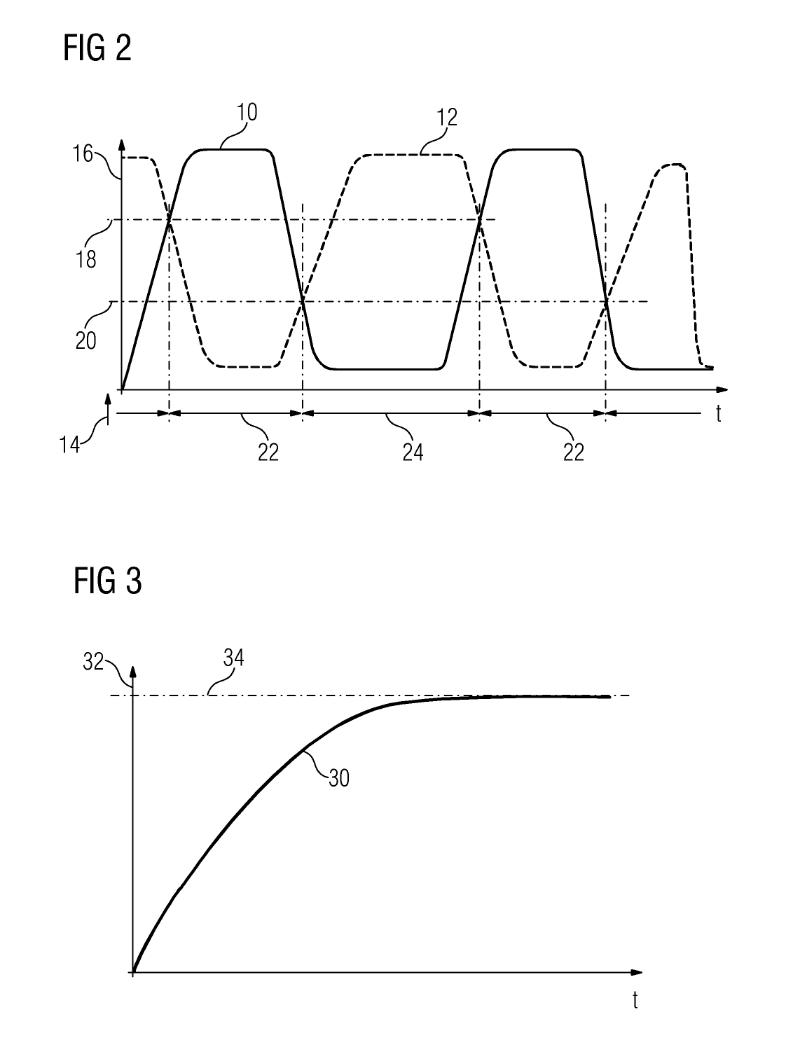

In FIG. 2 an activity curve 10 of the Default Mode Network and an activity curve 12 of the Task Positive Network are represented by way of example in order to describe an example embodiment of the invention. In the case of a patient with depression, the receptor occupation in the dopaminergic system is to be measured in the resting state.

To this end, 18F dopa was injected into the patient as a tracer at time instant 14 and the patient was placed directly into an MRT device. fMRT data was then measured at rest with the aid of a functional magnetic resonance tomography and a check was thereupon carried out to determine whether the Default Mode Network indicates the typically coherent activity or whether Task Positive Networks are active.

The times 22 with a predominant Default Mode Network Activity, i.e. the times after which the activity values 16 of the activity curve 10 of the Default Mode Network exceed an upper activity threshold value 18 and the activity values 16 of the activity curve 12 of the Task Positive Network do not reach the upper activity threshold value 18, are determined. Likewise the times 24 with a predominant Task Positive Network Activity, i.e. the times after which the activity values 16 of the activity curve 10 of the Default Mode Network do not reach a lower activity threshold value 20 and the activity values 16 of the activity curve 12 of the Task Positive Network exceed the lower activity threshold value 20, are determined.

If the Task Positive Network Activity is predominant, an indication is output for instance that the data is not useable. Alternatively, results of a subsequent positron emission tomography are set to zero. With a “mixed” activity distribution, i.e. an activity distribution in which parts of both networks are present, the results of the positron emission tomography can be corrected. E.g. FIG. 2 shows a distribution between activities of the Default Mode Network and the Task Positive Network of approximately 60:40. In this case, the positron emission tomography image could be corrected such that the signals from the Default Mode Network areas, e.g. medial lobus temporalis, medial prefrontal cortex, posterior congulum, are amplified accordingly and the signals from the Task Positive Network areas, e.g. intraparietal sulcus, are attenuated since here the activation was unwanted.

FIG. 3 shows by way of example a PET tracer accumulation curve 30 over time t. Since the accumulation 32 over time t does not take place evenly, but instead generally corresponds to a saturation kinetics, similar to a logarithm function which approaches a limit value 34, the contribution of the individual phases can be weighted accordingly. To this end, a kinetics can be assumed for instance across a calibration curve, which was determined in pre-examinations. Or the examination is implemented in a combined MR-PET device and the accumulation is determined in the PET over time.

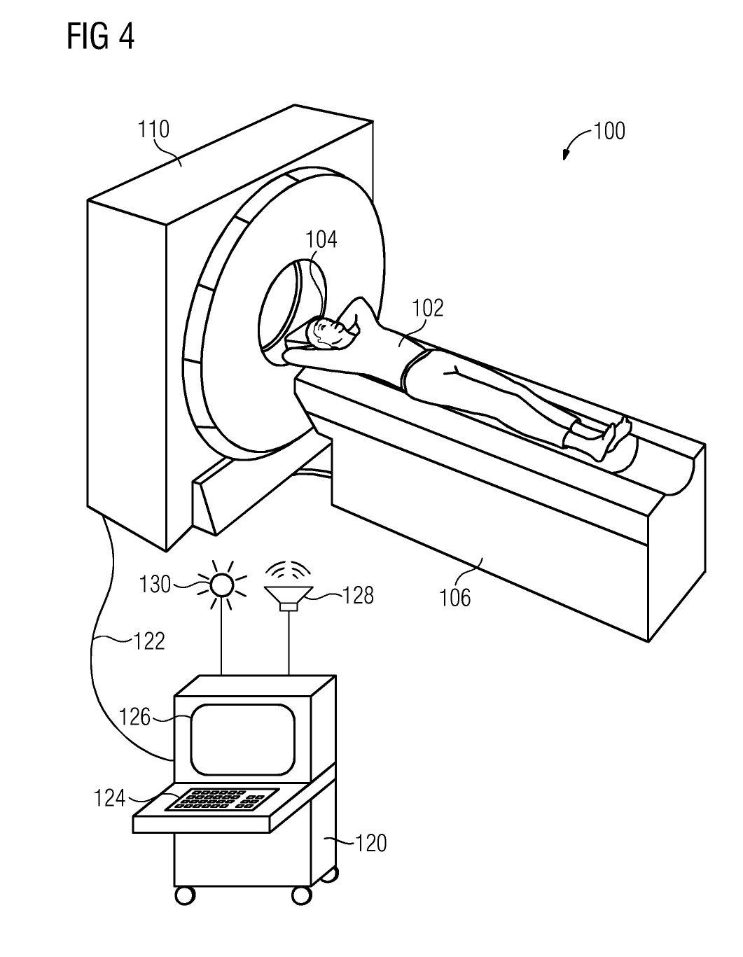

Finally, in FIG. 4, an apparatus 100 for implementing a positron emission tomography of an examination object 102, here a human patient, is shown symbolically. The examination object is on a support device 106, here a patient couch, the examination area involves brain areas 104. The apparatus 100 for implementing a positron emission tomography of an examination object 102 includes a positron emission tomography device and an MRT device, which are combined in a PET-MRTdevice 110 as a PET sub device and MRT sub device, and a computing and control unit 120, here in the form of a computer.

The MRT sub device is embodied, after inserting a PET tracer into the examination object 120, to implement at least one functional magnetic resonance tomography so as to determine at least one measure of the activation of at least one predeterminable brain area 104 in each instance and to make the at least one measure available to the computing and control unit 120. The PET sub device is embodied so as to implement a positron emission tomography of the examination object 102 and to make the result available to the computing and control unit 120.

The computing and control unit 120 is configured to this end so as to adjust the result of the positron emission tomography of the examination object 102 as a function of the at least one measure of the activation of the at least one predeterminable brain area 104. The computing and control unit 120 is equipped with data interfaces with the PET sub device and the MRT sub device, so that data, in particular image data, can be routed from these devices to the computing and control unit 120 by way of a data line 122. The computing and control unit 120 is furthermore configured to this end so as to adjust the result of the positron emission tomography of the examination object 102 as a function of the at least one measure of the activation of the at least one predeterminable brain area 104, by it having a corresponding computer program for instance, which executes these functions. The computing and control unit 120 has an input device 124, for example a computer keyboard, for entering threshold values for instance, in order to control the method and/or to terminate a repetition of the method, by actuating a button.

The apparatus 100 and in particular the computing and control unit 120 can be configured to execute one of the previously described methods, for instance by way of a computer program, which is stored in the memory of the computing and control unit 120 and is processed. The apparatus 100 further has an optical output device 130, for example a lamp, for outputting an optical signal and has an acoustic output device 128, for example a loudspeaker, for outputting an acoustic signal, in order to wake a patient for instance if an unwanted sleeping state is detected.

An output device 126, for example a computer monitor, is used to output a result of a positron emission tomography, which is preferably adjusted as a function of the at least one measure of the activation of at least one predeterminable brain area 104.

To summarize, some basic ideas of at least one embodiment of the invention are repeated. With a conventional psychiatric or neurological MR-PET examination, there is no possibility of detecting status changes in a patient during an accumulation of a tracer and in particular distinguishing between various neuronal networks which function with different neurotransmitters. It was therefore previously also not possible to correct results obtained from a MR-PET examination as a function of detected status changes in the patient.

At least one embodiment of the present invention proposes inter alia to implement an MRT measurement between the injection of a PET tracer and a PET measurement, said MRT measurement measuring the activation of predeterminable brain areas by way of the method of functional MRT. In this way these measurement results check whether the activation of the neuronal networks corresponds to expectations during the accumulation of the tracer. If this is not the case, either a corresponding warning is output to the user or the data is corrected. An essential advantage resulting herefrom involves more precise results of the PET examination, which enable for instance an improved diagnosis of a psychiatric or neurological disease.

What is claimed is:

1. A method for implementing a positron emission tomography of an examination object, wherein after introduction of a PET tracer into the examination object, the method comprises:
implementing at least one respective functional magnetic resonance tomography for determining at least one respective measure of the activation of at least one respective brain area;
implementing a positron emission tomography; and
adjusting a result of the implemented positron emission tomography as a function of the at least one respective measure of the activation of at least one respective brain area.

2. The method of claim 1, wherein the determination of the at least one respective measure of the activation of at least one respective brain area is repeatedly implemented by functional magnetic resonance tomography.

3. The method of claim 2, wherein the repeated determination of the at least one respective measure of the activation of at least one respective brain area by functional magnetic resonance tomography takes place at least during the period of time of accumulation of the PET tracer.

4. The method of claim 1, wherein the respective brain areas include at least one of brain areas of the Default Mode Network and brain areas of the Task Positive Network.

5. The method of claim 1, wherein the respective brain areas include brain areas of the Default Mode Network and by brain areas of the Task Positive Network and wherein the adjustment of the result of the positron emission tomography is determined as a function of the relationship from the measures of the activity distribution of the Default Mode Network and the Task Positive Network.

6. The method of claim 1, wherein a warning is output upon a measure of the at least one respective measure of the activation of at least one respective brain area lying outside of a tolerance range.

7. The method of claim 1, wherein a time is included in the adjustment of the result of the positron emission tomography, during which the at least one respective measure of the activation of the at least one respective brain area is above a threshold value.

8. The method of claim 2, wherein, after determining the at least one respective measure of the activation of at least one respective brain area, the at least one respective measure is compared with an activation threshold value and upon the at least one respective measure of the activation of at least one respective brain area being greater than the activation threshold value, an action is executed.

9. The method of claim 1, wherein an accumulation of the PET tracer in the examination object over time is included in the adjustment of the result of the positron emission tomography.

10. The method of claim 9, wherein the accumulation of the PET tracer in the examination object is approximated over time by way of a saturation function or is determined by a measurement with a PET MRT device.

11. The method of claim 2, wherein a segmentation of the brain is included in the determination of the at least one respective measure of the activation of at least one respective brain area, said segmentation being determined by way of a measurement of the accumulation of the PET tracer with the PET part of a PET-MRT device and transmitted to an MRT image, obtained with the MRT part of the PET-MRT device.

12. The method of claim 1, wherein a brain atlas is included in the determination of the at least one respective measure of the activation of at least one respective brain area.

13. An apparatus for implementing a positron emission tomography of an examination object, comprising:
a positron emission tomography device;
an MRT device; and
a computing and control device, wherein the MRT device is configured, after introduction of a PET tracer into the examination object, to implement at least one functional magnetic resonance tomography for determining at least one respective measure of activation of at least one respective brain area and to make the at least one respective measure available to the computing and control unit, and wherein the positron emission tomography device is configured to implement a positron emission tomography of the examination object and to make the result available to the computing and control unit, and wherein the computing and control unit is configured to adjust the result of the positron emission tomography of the examination object as a function of the at least one respective measure of the activation of at least one respective brain area.

14. An apparatus for implementing a positron emission tomography of an examination object, comprising:
a positron emission tomography device;
an MRT device; and
a computing and control device, wherein the MRT device is configured, after introduction of a PET tracer into the examination object, to implement at least one functional magnetic resonance tomography for determining at least one respective measure of activation of at least one respective brain area and to make the at least one respective measure available to the computing and control unit, and wherein the positron emission tomography device is configured to implement a positron emission tomography of the examination object and to make the result available to the computing and control unit, and wherein the computing and control unit is configured to adjust the result of the positron emission tomography of the examination object as a function of the at least one respective measure of the activation of at least one respective brain area, configured to execute the method of claim 2.

15. An apparatus for implementing a positron emission tomography of an examination object, comprising:
a positron emission tomography device;
an MRT device; and
a computing and control device, wherein the MRT device is configured, after introduction of a PET tracer into the examination object, to implement at least one functional magnetic resonance tomography for determining at least one respective measure of activation of at least one respective brain area and to make the at least one respective measure available to the computing and control unit, and wherein the positron emission tomography device is configured to implement a positron emission tomography of the examination object and to make the result available to the computing and control unit, and wherein the computing and control unit is configured to adjust the result of the positron emission tomography of the examination object as a function of the at least one respective measure of the activation of at least one respective brain area, wherein the positron emission tomography device and the MRT device are combined in a PET-MRT device and wherein the PET MRT device and the computing and control unit are configured to execute the method of claim 11.

16. The method of claim 1, wherein the implementing of at least one respective functional magnetic resonance tomography, the implementing a positron emission tomography, and the adjusting of the result of the implemented positron emission tomography are repeatedly executed, and wherein a repetition rate is determinable.

17. The method of claim 8, wherein the action includes outputting of at least one of an acoustic, optical and tactile signal.

18. The method of claim 1, wherein a segmentation of the brain is included in the determination of the at least one respective measure of the activation of at least one respective brain area, said segmentation being determined by way of a measurement of the accumulation of the PET tracer with the PET part of a PET-MRT device and transmitted to an MRT image, obtained with the MRT part of the PET-MRT device.

19. The apparatus of claim 13, wherein the positron emission tomography device and the MRT device are combined in a PET-MRT device.
